(19) United States
(12) Patent Application Publication
(10) Pub. No.: US 2010/0212735 A1
(43) Pub. Date: Aug. 26, 2010

(54) SOLAR CELL AND METHOD FOR FABRICATING THE SAME

(76) Inventors: Pin-Sheng Wang, Hsinchu County (TW); Yi-Chin Chou, Changhua County (TW); Shih-Cheng Lin, Hsinchu County (TW); Shih-Yu Huang, Taipei County (TW); Chia-Chen Tu, Taichung County (TW)

Correspondence Address: NORTH AMERICA INTELLECTUAL PROPERTY CORPORATION, P.O. BOX 506, MERRIFIELD, VA, 22116, US

(21) Appl. No.: 12/652,744

(22) Filed: Jan. 6, 2010

Related U.S. Application Data
(60) Provisional application No. 61/155,162, filed on Feb. 25, 2009.

(51) Int. Cl. H01L 31/00; H01L 31/18

(52) U.S. Cl. 136/256; 438/73; 257/E31.032; 257/E21.085

(57) ABSTRACT

This invention discloses a high-efficiency solar cell structure which enables high throughput manufacturing process thereof. The solar cell is accomplished by forming a plurality of first emitter regions in a front surface of a substrate, a plurality of second emitter regions in the front surface, and a plurality of fingers. Each of the fingers is formed over a least a portion of the second emitter region and a portion of the first emitter region. The first emitter regions and the second emitter regions have a depth not less than 0.2 μm.

### CROSS REFERENCE TO RELATED APPLICATIONS

This application claims priority to and the benefit of U.S. Provisional Patent Application Ser. No. 61/155,162, filed on Feb. 25, 2009.

### BACKGROUND OF THE INVENTION

1. Field of the Invention

The present invention relates to solar cell, and a method for fabricating a solar cell using a screen-printing process.

2. Description of the Prior Art

The emitter region of silicon solar cells materially impacts the total light converting efficiency. An optimized emitter design has to consider two different areas on the surface of the so-called selective emitter solar cell: the area under fingers and the area between the fingers. In order to reduce electron-hole recombination effect in the area between the fingers, relatively higher surface resistance emitters are applied, while a relatively lower surface resistance directly under each finger provides a lower surface resistance.

The advantages of having two different regions in the pn-junction are well understood, in that higher Isc, Voc and improved FF can result from lower electron-hole recombination effect near the surface of semiconductor substrate.

In addition, the width of the emitter region under each finger is made as narrow (preferably 30 to 60 μm) as possible in order to reduce the possibility of electron-hole recombination, and the depth of the emitter region between two fingers is made as shallow (no greater than 2 μm) as possible in order to gain a better response in the near UV area. Upon the emitter profile described above, finger shall be highly aligned in order to prevent the short circuit during the metallization.

Thus, to fabricate such a solar cell, the fingers are formed by a costly and complicated process wherein highly precise alignment is required. For example, prior art methods may include electroplating, electroless-plating process or other metal self-aligned process and followed by heating at a suitable temperature for a sufficient period of time.

Some techniques for fabricating such a solar cell have been disclosed. For example, U.S. Pat. No. 5,871,591 issued to Douglas S. Ruby entitled Silicon Solar Cells Made by a Self-aligned, Selective emitter, Plasma-Etchback Process, U.S. Pat. No. 6,277,667 issued to Chorng-Jye Huang entitled Method for Fabricating Solar Cell, and U.S. Pat. No. 6,524,880 issued to In-sik Moon entitled Solar Cell and Method for Fabricating the Same disclosed the self-alignment process for forming the metal contact.

However, the above-mentioned prior art techniques use several photo-etching or electroplating processes, which are costly, time-consuming and difficult to apply to mass production.

### SUMMARY OF THE INVENTION

An objective of this invention is to provide an electrode profile in the front side of solar cell which can be fabricated by screen printing process.

Another objective of this invention is to provide a method for manufacturing selective emitter solar cell, which is cost effective.

Further, this invention provides emitter profiles for selective emitter solar cells which can be used to prevent short circuit during the metallization made by the screen printing.

In accordance with the above objectives, a selective emitter solar cell structure and a method for making the same has been devised which allows such selective emitter solar cells to be economically and efficiently fabricated by the screen printing process.

In accordance with one embodiment, this invention provides a crystalline silicon solar cell including a plurality of first emitter regions formed in a front surface of the solar cell with a relatively higher surface resistance; a plurality of second emitter regions formed in the front surface with a relatively lower surface resistance; and a plurality of fingers each of which is formed over at least a portion of the second emitter region and a portion of the first emitter region.

In accordance with another embodiment, this invention provides a method for fabricating a crystalline solar cell, comprising the steps of providing a semiconductor substrate; forming a plurality of first emitter regions in a front surface of the semiconductor substrate; forming a plurality of second emitter regions in the front surface of the semiconductor substrate; forming an oxide layer onto the front surface of the semiconductor substrate; and forming a plurality of fingers covering at least a portion of the second emitter regions and a portion of the first emitter regions.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The present invention can be better understood from the detailed description of the invention given hereinafter and from the accompanying drawings which are given by way of illustrations or flow charts, wherein,

FIGS. 1a-1c show three exemplary solar cell structures according to preferred embodiments of the present invention;

FIG. 2 shows the process flow for fabricating the solar cell featuring that the N+ diffusion is formed before the formation of the N− diffusion.

FIG. 3 shows the process flow for fabricating the solar cell featuring that the N− diffusion is formed before the formation of the N+ diffusion.

FIG. 4 shows the process flow for fabricating the solar cell featuring that the N− and N+ diffusions are formed at the same time.

### DETAILED DESCRIPTION

The present invention pertains to a high-efficiency solar cell with a simplified structure, which enables a high throughput manufacturing process thereof.

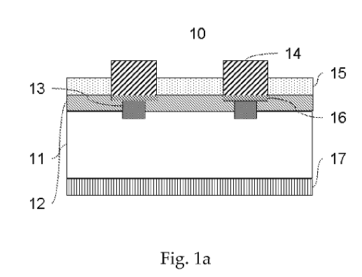

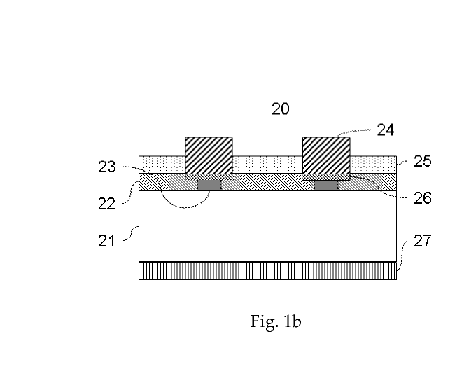

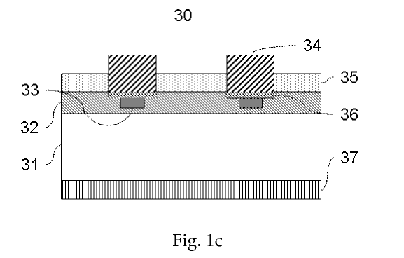

As shown in FIGS. 1a-1c, from one aspect, the invention provides a solar cell (10, 20, 30) comprising (i) a semiconductor substrate (11, 21, 31), (ii) a plurality of first emitter regions (12, 22, 32) formed under in a front surface of the semiconductor substrate (11, 21, 31), (iii) a plurality of second emitter regions (13, 23, 33) formed in the same surface with the first emitter regions, (iv) a field region (17, 27, 37) formed in the opposite surface of the semiconductor substrate, (v) a plurality of fingers (14, 24, 34), each of which is formed over at least a portion of the second emitter region (13, 23, 33) and a portion of the first emitter region (12, 22, 32), and (vi) a plurality of metal-semiconductor contact (MSC) (16, 26, 36), which provide good ohmic contact between the finger(14, 24, 34), first emitter region (12, 22, 32) and second emitter region (13, 23, 33). The first emitter regions (12, 22, 32) and second emitter regions (13, 23, 33) are interspersed in the front surface of the semiconductor substrate (11, 21, 31).

The semiconductor substrate (11, 21, 31) preferably comprises p-type doped silicon, and the first emitter regions (12, 22, 32) and second emitter regions (13, 23, 33) are preferably formed by doping an n-type material, such as phosphorous. The field region (17, 27, 37) is preferably formed by doping a p-type dopant material comprising, for example, pure aluminum or an alloy of aluminum and silicon.

The surface resistance of the first emitter regions (12, 22, 32) is in the range of 80 ohm/square to 400 ohm/square, and preferably in the range from about 90 ohm/square to about 180 ohm/square. The surface resistance of second emitter regions (13, 23, 33) is in the range from about 5 ohm/square to 80 ohm/square, and preferably in the range from about 20 ohm/square to about 60 ohm/square.

Furthermore, the depths of the first emitter regions (12, 22, 32) and second emitter regions (13, 23, 33) are both preferably not less than about 0.2 μm and the relation to the depth of the first emitter regions (12, 22, 32) and second emitter regions (13, 23, 33) can be in any of the following conditions: (i) the depth of first emitter region (12) is less than the depth of the second emitter region (13) as shown in FIG. 1a; (ii) the depth of first emitter region (22) is similar to the depth of the second emitter region (23) as shown in FIG. 1b; and (iii) the depth of first emitter region (32) is greater than the depth of the second emitter region (33) as shown in FIG. 1c. The configuration as shown in FIG. 1a is a more preferred embodiment. Preferably, the depth of first emitter region (12) is less than the depth of the second emitter region (13).

The solar cell is further preferably provided with an antireflective layer (15, 25, 35) formed over the same surface with the first emitter regions (12, 22, 32) and second emitter regions (13, 23, 33) of the semiconductor substrate.

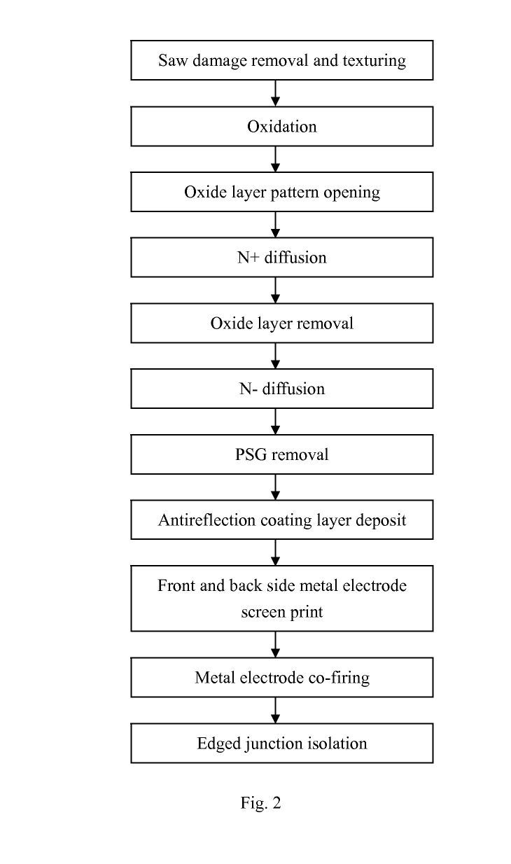

As shown in FIGS. 2-4, from a process aspect, the invention provides a method of fabricating a solar cell having a plurality of fingers (14), each of which is formed over at least a portion of the second emitter region (13) and a portion of the first emitter region (12). The method includes the steps of: providing a semiconductor substrate (11), forming a plurality of first emitter regions (12), forming a plurality of second emitter regions (13) in the same surface with the first emitter regions (12), forming field region (17) in the opposite surface of the semiconductor substrate (11), forming an oxide layer on the same surface with the first and second emitter regions, removing the oxide layer, printing metal paste covering over at least a portion of the second emitter region and a portion of the first emitter region, and heating the semiconductor substrate (11) for a sufficient period of time to form a plurality of fingers (14) and a plurality of MSC (16).

The oxide layer is formed over the surface of the semiconductor substrate (11) at a high temperature in an oxygen-rich environment and is then removed before the step of metallization.

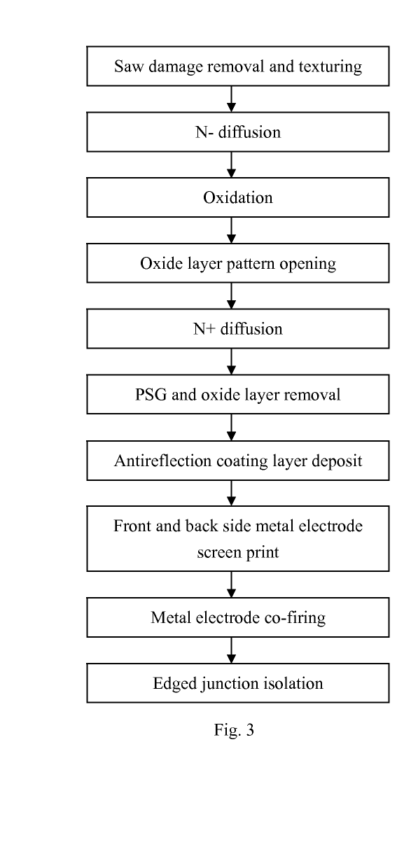

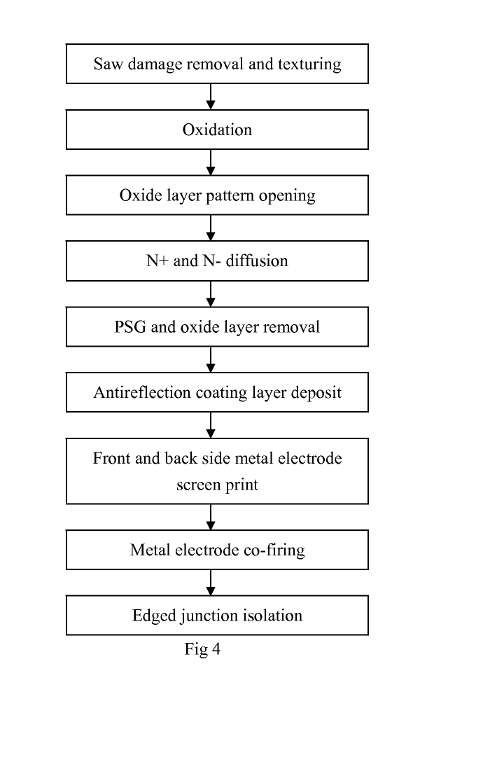

The steps of forming the first and second emitter regions (12, 13) can be conducted under any of the following conditions: (i) the step of forming first emitter regions (12) is prior to the step of forming second emitter regions (13) as shown in the FIG. 3; (ii) the step of forming first emitter regions (12) is performed after the step of forming second emitter regions (13) as shown in FIG. 2; (iii) the first emitter regions (12) and the second emitter regions (13) are formed substantially at the same time as shown in FIG. 4.

Furthermore, the location of the second emitter regions (13) is designed by oblation of predetermined portion of the oxide layer by methods including but not limited to (i) etching paste; (ii) photolithography; (iii) inkjet printing, and (iv) laser.

The semiconductor substrate (11) is preferably doped by p-type materials and having a surface resistance ranging from approximately 0.5 ohm/square to 6 ohm/square. The first and second emitter regions (12, 13) are preferably formed using n-type dopant material, while the field region (17) in the opposite surface of the semiconductor substrate is formed. The finger (14) is formed over a second emitter region (13) and a portion of first emitter region (11) by depositing the metal paste. Options for the metal paste include but are not limited to DuPont PV series, FERRO 33-462, Heraeus SOL-9118A, and Noritake NP-4682C.

Upon completion of the first emitter regions (12), the first emitter regions (12) will have a depth not less than about 0.2 μm and a surface resistance in a range of 80 to 400 ohm/square and preferably in the range from about 90 ohm/square to about 180 ohm/square.

Upon completion of the second emitter regions (13), the second emitter regions (13) will have a depth not less than about 0.2 μm and a surface resistance of the range from about 5 ohm/square to about 80 ohm/square and preferably in the range from about 20 ohm/square to about 60 ohm/square.

The step of fingers (14) and the MSC (14) is conducted by depositing a metal paste to cover a second emitter region and a portion of the first emitter region by any of the following methods: screen printing, transfer coating, printing, thermal inkjet printing, electro-deposition, eletroless plating, or electroplating. Heating the semiconductor substrate (11) at 350˜950° C. for a sufficient time is followed by depositing the metal paste as described above.

The invention provides a number of advantages over the prior art solar cells and the manufacturing methods thereof. The combination of lower surface resistance regions and higher surface resistance regions in the p-n junction of the solar cell acts to minimize the electron-hole recombination effect. The tolerance of the finger covering a portion of first emitter regions results in a lower cost and high throughput process that can be used, for example, in the existing screen printing process.

In view of the foregoing description of a preferred embodiment of this invention, various additional alternations, modifications, variations, and obvious substitutions will occur to those skilled in the art. It, therefore, should be understood that the above description of the invention is intended to be illustrative only, and in no way limiting the scope of the invention. The invention rather should be understood as being limited only by the terms of the appended claims.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A crystalline silicon solar cell, comprising:
a plurality of first emitter regions formed in a front surface of said solar cell with a relatively higher surface resistance;
a plurality of second emitter regions formed in said front surface with a relatively lower surface resistance; and
a plurality of fingers each of which is formed over at least a portion of said second emitter region and a portion of said first emitter region.

2. The crystalline silicon solar cell according to claim 1 wherein said first emitter regions have a depth not less than 0.2 μm.

3. The crystalline silicon solar cell according to claim 1 wherein said second emitter regions have a depth not less than 0.2 μm.

4. The crystalline silicon solar cell according to claim 1 wherein said relatively higher surface resistance of said first emitter regions is in the range from approximately 80 to 400 ohm/square.

5. The crystalline silicon solar cell according to claim 1 wherein said relatively higher surface resistance of said first emitter regions is in the range of from approximately 90 to 180 ohm/square.

6. The crystalline silicon solar cell according to claim 1 wherein said relatively lower surface resistance of said second emitter regions is in the range from approximately 5 to 80 ohm/square.

7. The crystalline silicon solar cell according to claim 1 wherein said relatively lower surface resistance of said second emitter regions is in the range from approximately 20 to 60 ohm/square.

8. The crystalline silicon solar cell according to claim 1 wherein a width of each of said fingers is not less than a width of each of said second emitter regions.

9. The crystalline silicon solar cell according to claim 1 wherein said fingers are formed by depositing a metal over a semiconductor surface by a method selected from a group consisting of: (1) screen printing, (2) transfer coating, (3) printing, (4) thermal inkjet printing, (5) electro-deposition, (6) eletroless plating, and (7) electroplating.

10. The crystalline silicon solar cell according to claim 9 wherein said metal comprises sliver.

11. The crystalline silicon solar cell according to claim 9 wherein said metal comprises silver paste.

12. The crystalline silicon solar cell according to claim 11 wherein said silver paste comprises DuPont PV145, PV159, FERRO 33-462, Heraeus SOL-9118A or Noritake NP-4682C.

13. A method for fabricating a crystalline solar cell, comprising the steps of providing a semiconductor substrate;
forming a plurality of first emitter regions in a front surface of said semiconductor substrate;
forming a plurality of second emitter regions in said front surface of said semiconductor substrate;
forming an oxide layer onto said front surface of said semiconductor substrate; and
forming a plurality of fingers covering at least a portion of said second emitter regions and a portion of said first emitter regions.

14. The method according to claim 13 wherein said oxide layer is removed before forming said plurality of fingers.

15. The method according to claim 13 wherein said first emitter regions have a depth not less than 0.2 μm.

16. The method according to claim 13 wherein said second emitter regions have a depth not less than 0.2 μm.

17. The method according to claim 13 wherein said first emitter regions have a surface resistance in the range from approximately 80 to 400 ohm/square.

18. The method according to claim 13 wherein said first emitter regions have a surface resistance in the range of from approximately 90 to 180 ohm/square.

19. The method according to claim 13 wherein said second emitter regions have a surface resistance in the range from approximately 5 to 80 ohm/square.

20. The method according to claim 13 wherein said second emitter have a surface resistance in the range from approximately 20 to 60 ohm/square.

21. The method according to claim 13 wherein said first emitter regions and said second emitter regions are interspersed in said front surface of said semiconductor substrate.

22. The method according to claim 13 wherein said second emitter regions are conducted by oblation of predetermined portion of said oxide layer by a method selected from a group consisting of: (1) etching paste; (2) photolithography; (3) inkjet printing and (4) laser.

23. The method according to claim 13 wherein said fingers are formed by depositing metal paste on said front surface of said semiconductor substrate.

24. The method according to claim 13 wherein said fingers are formed by heating said semiconductor substrate for a duration in a temperature of about 700-950 ° C.

25. The method according to claim 13 wherein a width of each of said fingers is not less than a width of each of said second emitter region.

26. The method according to claim 13 wherein said metal paste comprises DuPont PV145, PV159, FERRO 33-462, Heraeus SOL-9118A and Noritake NP-4682C.
